(19) United States
(12) Patent Application Publication
(10) Pub. No.: US 2013/0249047 A1
(43) Pub. Date: Sep. 26, 2013

(54) THROUGH SILICON VIA STRUCTURE AND METHOD FOR FABRICATING THE SAME

(71) Applicants: Chih-Hsiung Hung, Taipei City (TW); Yi-Jen Lo, New Taipei City (TW)

(72) Inventors: Chih-Hsiung Hung, Taipei City (TW); Yi-Jen Lo, New Taipei City (TW)

(73) Assignee: NANYA TECHNOLOGY CORPORATION, Taoyuan (TW)

(21) Appl. No.: 13/429,444

(22) Filed: Mar. 26, 2012

(51) Int. Cl. H01L 29/06; H01L 21/762

(52) U.S. Cl. 257/506; 438/424; 257/E29.02; 257/E21.546

(57) ABSTRACT

A through silicon via structure is provided, including a substrate, an isolation layer, a conductive layer and a dielectric layer. The substrate has a through-hole therein. The isolation layer is disposed on two sidewalls of the through-hole. The conductive layer is disposed in the through-hole and covers the isolation layer, and the conductive layer includes a first portion and a second portion, wherein the first portion fills a portion of the through-hole, and the second portion is located on the sidewalls in the other portion of the through-hole, such that the conductive layer has a concave part. The dielectric layer is disposed in the concave part and fills the concave part.

### BACKGROUND OF THE INVENTION

1. Field of the Invention

The present invention generally relates to a through silicon via structure and a method for fabricating the same, in particular, to a through silicon via structure and a method for fabricating the same for 3D IC technology application.

2. Description of Related Art

With the progress of technology, nowadays consumers pay more attention to characteristics of portable electronic products such as size, integrity and efficiency. This also elevates the needs of the miniaturization of semiconductors and cost reduction in manufacturing processes. 3D IC technology has been developed in recent years, in which semiconductor chips could be vertically stacked by techniques such as bonding or packaging, and through silicon vias are utilized to connect chips in each layer. The through silicon via may provide a vertically conducting path, and may have advantages such as increasing the stacked density of chips, elevating efficiency of products and lowering energy consumption. Therefore, by utilizing 3D IC technology, higher integrity and efficiency may be realized in small volume products.

Conventional through silicon via structure is a solid core structure filled with metal or other conductive materials. However, the material cost of filling through silicon vias in this way would be higher, and due to the difference in the coefficients of the thermal expansion (CTE) between the substrate and the via-filling material, the phenomenon of thermal expansion and contraction caused by temperature changes in subsequent manufacturing processes would generate a stress between the via-filling material and the substrate, thereby causing adverse effects on devices around the through silicon via. Therefore, a through silicon via structure which could reduce above stress effect and lower the material cost is needed to be developed.

### SUMMARY OF THE INVENTION

Accordingly, the invention provides a through silicon via structure and a method for fabricating the same, which could reduce the stress generated between the via-filling material and the substrate, thereby preventing adverse effects on the efficiency of devices around the through silicon via, and also lowering the material cost.

The invention provides a method for fabricating a through silicon via structure, which could lower the material cost.

A through silicon via structure is provided, including a substrate, an isolation layer, a conductive layer and a dielectric layer. The substrate has a through-hole therein. The isolation layer is disposed on two sidewalls of the through-hole. The conductive layer is disposed in the through-hole and covers the isolation layer, and the conductive layer includes a first portion and a second portion, wherein the first portion fills a portion of the through-hole, and the second portion is located on the sidewalls in the other portion of the through-hole, such that the conductive layer has a concave part. The dielectric layer is disposed in the concave part and fills the concave part.

According to an embodiment of the invention, the aforementioned through silicon via structure further includes a seed layer disposed between the isolation layer and the conductive layer.

According to an embodiment of the invention, in the aforementioned through silicon via structure, a height of the first portion is, for example, 15% to 50% of a depth of the through-hole.

According to an embodiment of the invention, in the aforementioned through silicon via structure, a thickness of the second portion located on each of the sidewalls is, for example, 5% to 10% of a width of the through-hole.

According to an embodiment of the invention, in the aforementioned through silicon via structure, the depth of the through-hole is, for example, 10 to 100 μm.

According to an embodiment of the invention, in the aforementioned through silicon via structure, the width of the through-hole is, for example, 5 to 50 μm.

According to an embodiment of the invention, in the aforementioned through silicon via structure, the height of the first portion is, for example, 5 to 25 μm.

According to an embodiment of the invention, in the aforementioned through silicon via structure, the thickness of the second portion located on each of the sidewalls is, for example, 1 to 2. μm.

According to an embodiment of the invention, in the aforementioned through silicon via structure, a material of the conductive layer is, for example, copper, poly silicon or tungsten.

According to an embodiment of the invention, in the aforementioned through silicon via structure, a material of the dielectric layer is, for example, a porous dielectric material.

According to an embodiment of the invention, in the aforementioned through silicon via structure, a material of the porous dielectric material is, for example, polymer or porous silicon dioxide.

A method for fabricating a through silicon via structure is further provided, which includes the following steps. A substrate is provided, which includes a first surface and a second surface, and the first surface of the substrate has an opening formed therein. An isolation layer is formed on the substrate conformally. A conductive layer is formed on the isolation layer, and the conductive layer located in the opening has a concave part. A dielectric layer filled the concave part is formed. The dielectric layer, the conductive layer and the isolation layer located outside the opening are removed. A portion of the substrate and a portion of the isolation layer are removed from the second surface of the substrate until the conductive layer is exposed, such that the opening becomes a through-hole. The conductive layer located in the through-hole includes a first portion and a second portion, wherein the first portion fills a portion of the through-hole, and the second portion is located on two sidewalls of the other portion of the through-hole.

According to an embodiment of the invention, the aforementioned method further includes forming a seed layer on the isolation layer conformally before forming the conductive layer.

According to an embodiment of the invention, in the aforementioned method, a method for removing the dielectric layer, the conductive layer and the isolation layer located outside the opening is, for example, chemical mechanical polishing (CMP).

According to an embodiment of the invention, in the aforementioned method, a method for removing a portion of the substrate and a portion of the isolation layer from the second surface of the substrate is, for example, chemical mechanical polishing (CMP).

According to an embodiment of the invention, in the aforementioned method, a height of the first portion is, for example, 15% to 50% of a depth of the through-hole.

According to an embodiment of the invention, in the aforementioned method, a thickness of the second portion located on each of the sidewalls is, for example, 5% to 10% of a width of the through-hole.

According to an embodiment of the invention, in the aforementioned method, a material of the conductive layer is, for example, copper, poly silicon or tungsten.

According to an embodiment of the invention, in the aforementioned method, a material of the dielectric layer is, for example, a porous dielectric material.

According to an embodiment of the invention, in the aforementioned method, material of the porous dielectric material is, for example, polymer or porous silicon dioxide.

Based on above, in the through silicon via structure provided in the invention, since the dielectric layer is disposed in the concave part of the conductive layer and fills the concave part, the stress generated between the via-filling material and the substrate may be reduced. Adverse effects on the devices around the through silicon via caused by the stress may further be prevented, thus the efficiency of the devices would be efficiently elevated. Furthermore, the method for fabricating the through silicon via structure provided in the invention could be easily incorporated into current manufacturing processes, and may lower the fabricating cost of the through silicon via structure.

In order to make the aforementioned features and advantages of this invention comprehensible, embodiments of the invention accompanied with figures are described in detail below.

### BRIEF DESCRIPTION OF THE DRAWINGS

FIGS. 1A-1E are cross-sectional views illustrating a manufacturing process for fabricating the through silicon via structure according to an embodiment of the invention. FIGS. 1F-1I are cross-sectional views illustrating a manufacturing process for fabricating a conductive structure in application of the through silicon via structure according to an embodiment of the invention.

### DESCRIPTION OF THE EMBODIMENTS

The embodiments of the invention will be fully described in detail along with the accompanying drawings in the following sections. However, the invention may be embodied by various forms, and is not limited to the embodiments described herein. Terms of orientation such as “on”, etc., in the following embodiments are only provided for reference to the accompany drawings; therefore, the terms of orientation are used for detailed description instead of limiting the invention. It should be understand that when a layer or component is described as being “on” another layer or component, it may be formed directly on the other layer or component, or additional layer(s) or component may be interposed therebetween. Besides, for clarity, the size and relative size of each layer in the accompany drawings may be exaggeratedly illustrated.

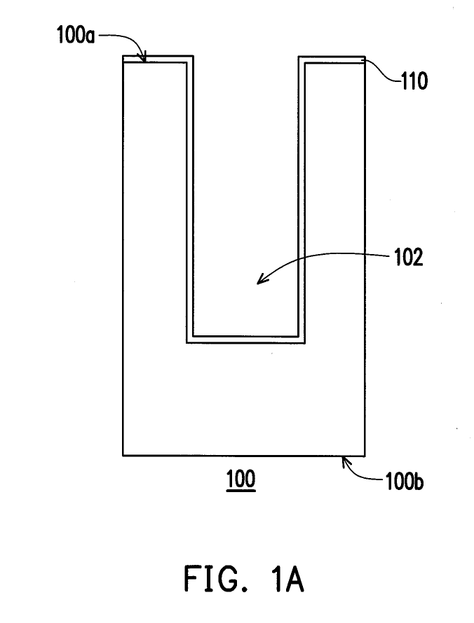

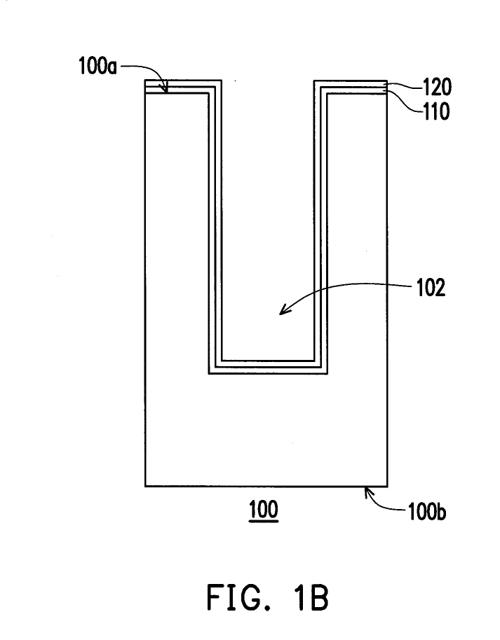

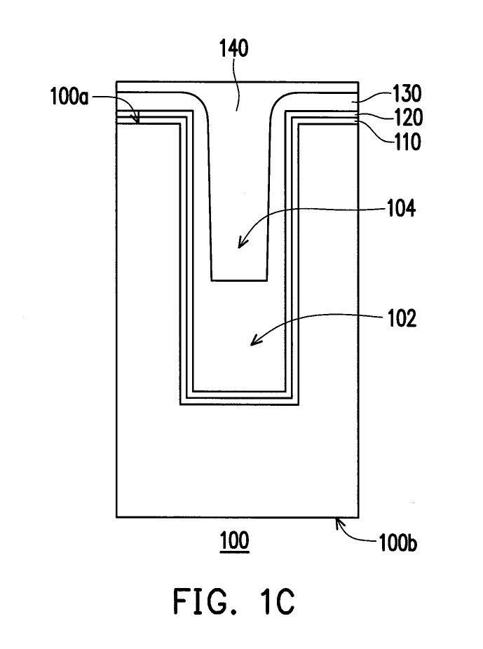

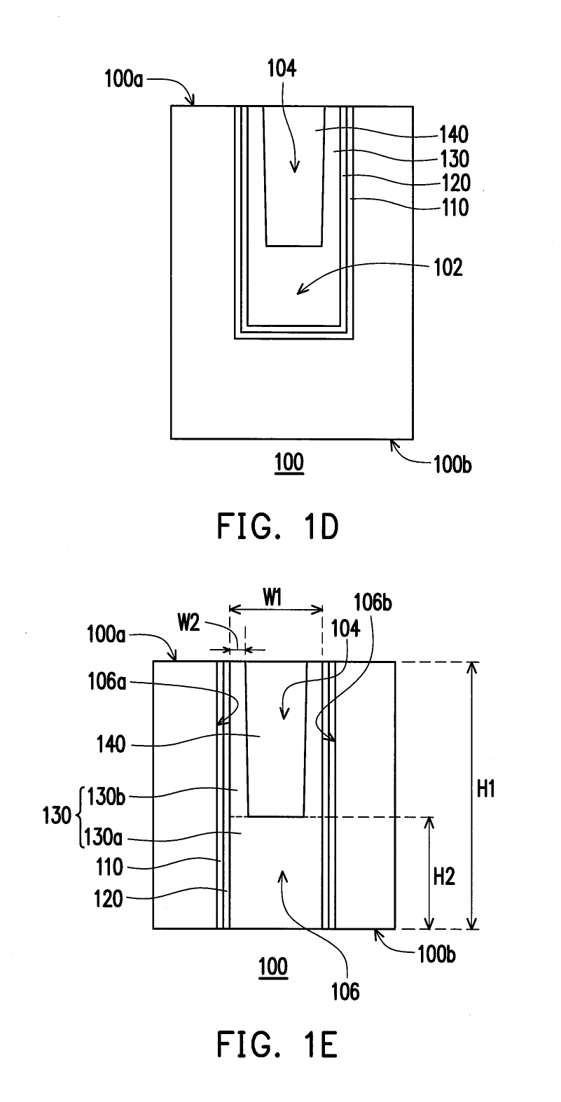

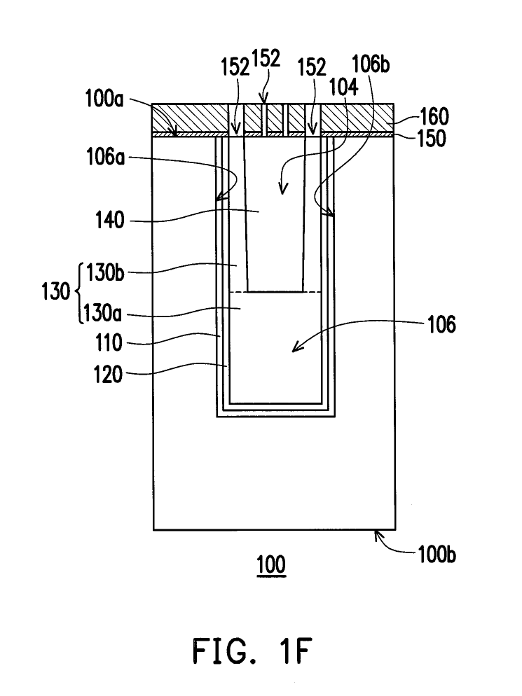

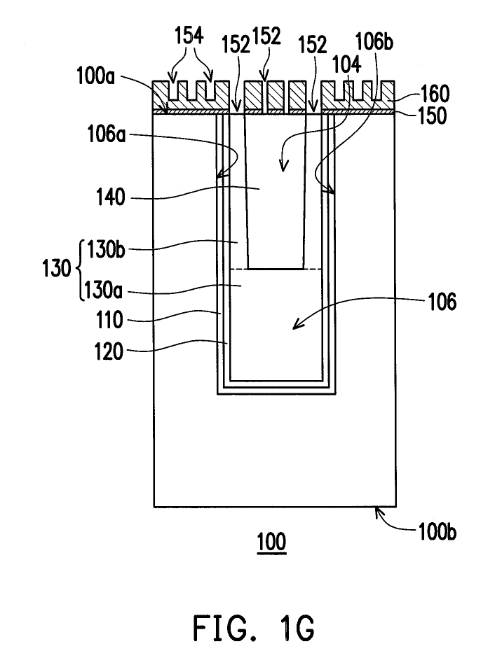

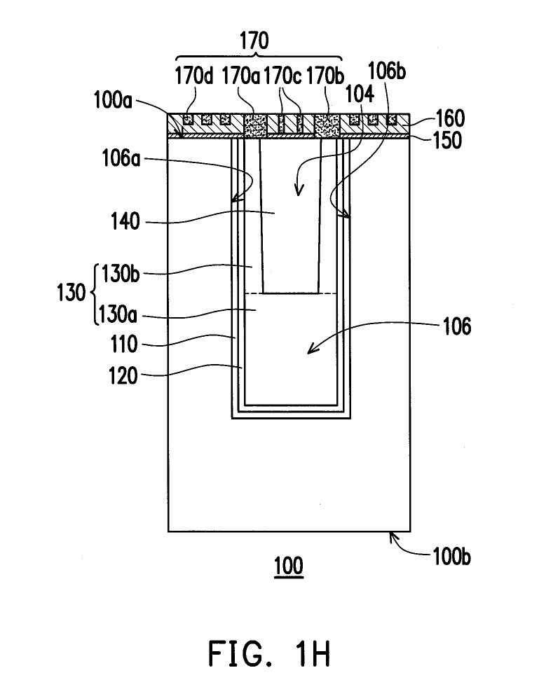

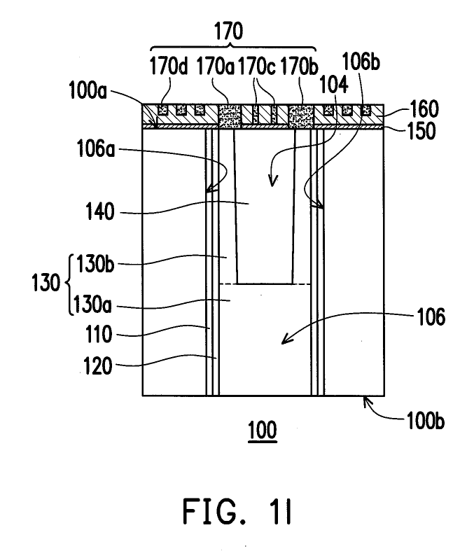

FIGS. 1A-1E are cross-sectional views illustrating a manufacturing process for fabricating the through silicon via structure according to an embodiment of the invention.

Referring to FIG. 1A, a substrate 100 is provided. The substrate 100 includes a first surface 100a and a second surface 100b, and the first surface 100a of the substrate 100 has an opening 102 formed therein. An isolation layer 110 is formed on the substrate 100 conformally. The material of the substrate 100 is, for example, silicon substrate, and the material of the isolation layer 110 is, for example, silicon dioxide, but the invention is not limited thereto. The method of forming the isolation layer 110 is, for example, chemical vapor deposition (CVD).

Referring to FIG. 1B, optionally, a seed layer 120 may be formed on the isolation layer 110 conformally. The method of forming the seed layer 120 is, for example, Ta, TaN or TiN by physical vapor deposition (PVD) or CVD, but the invention is not limited thereto.

It should be noted that in practice, whether to form the seed layer 120 and what kind of material is used as the material of the seed layer 120 will depend on the material used for a conductive layer 130 to be mentioned in the following paragraph. For example, if copper is used as the material of the conductive layer 130 to fill through silicon vias, then copper shall be selected as the material of the seed layer 120 for conducting subsequent processes.

Referring to FIG. 1C, the conductive layer 130 is formed on the seed layer 120, and the conductive layer 130 located in the opening 102 has a concave part 104. The material of the conductive layer 130 can be, for example, copper, poly silicon or tungsten. The forming method of the conductive layer is, for example, electrochemical plating (ECP), physical vapor deposition (PVD) or chemical vapor deposition (CVD), but the invention is not limited thereto.

A dielectric layer (or called stuffing layer) 140 is formed on the conductive layer 130, and the dielectric layer 140 fills the concave part 104. The material of the dielectric layer (stuffing layer) 140 is, for example, a polymer or a porous dielectric material to support the structure. For instance, polymers such as poly-phenylene benzobisoxazole (PBO) or porous silicon dioxide (SiO₂) may be used as the material of the dielectric layer 140. Specifically, when porous silicon dioxide is used as the material of the dielectric layer 140, the forming method of the dielectric layer 140 is, for, example, spin on glass (SOG) method. While using polymer as the material of the dielectric layer 140, the forming method of dielectric layer 140 is, for example, CVD, but the invention is not limited thereto.

Referring to FIG. 1D, the dielectric layer 140, the conductive layer 130, the seed layer 120 and the isolation layer 110 located outside the opening 102 are removed. The method for removing the dielectric layer 140, the conductive layer 130, the seed layer 120 and the isolation layer 110 located outside the opening 102 is, for example, chemical mechanical polishing (CMP).

Referring to FIG. 1E, a portion of the substrate 100, a portion of the seed layer 120 and a portion of the isolation layer 110 are removed from the second surface 100b of the substrate 100 until the conductive layer 130 is exposed, such that the opening 102 becomes a through-hole 106. The method for removing a portion of the substrate 100, a portion of the seed layer 120 and a portion of the isolation layer 110 from the second surface 100b of the substrate 100 is, for example, chemical mechanical polishing (CMP), but the invention is not limited thereto.

At this time, the conductive layer 130 located in the through-hole 106 includes a first portion 130a and a second portion 130b, wherein the first portion 130a fills a portion of the through-hole 106, and the second portion 130b is located on two sidewalls 106a and 106b of the other portion of the through-hole 106.

The height H2 of the first portion 130a is, for example, 15% to 50% of the depth H1 of the through-hole 106. The thickness W2 of the second portion 130b located on each of the sidewalls 106a and 106b is, for example, 5% to 10% of the width W1 of the through-hole 106. To be more specific, the depth H1 of the through-hole 106 is, for example, 10 to 100 μm, and the width W1 of the through-hole 106 is, for example, 5 to 50 μm. Furthermore, the height H2 of the first portion 130a is, for example, 5 to 25 μm, and the thickness W2 of the second portion 130b located on each of the sidewalls 106a and 106b is, for example, 1 to 2 μm.

Based on above embodiments, the method for fabricating the through silicon via structure could be easily incorporated into current manufacturing processes. Furthermore, since in the fabrication method, the conductive layer 130 used for forming the through silicon via only fills a portion of the through-hole 106, the amount of material used to form the conductive layer 130 of the through silicon via could be significantly reduced, thereby lowering the fabricating cost of the through silicon via structure.

Hereinafter, the through silicon via structure set out in above embodiments will be described by reference to FIG. 1E.

Referring to FIG. 1E again, the through silicon via structure of the embodiment includes a substrate 100, an isolation layer 110, a seed layer 120, a conductive layer 130 and a dielectric layer 140. The substrate 100 has a through-hole 106 therein. The isolation layer 110 is disposed on two sidewalls 106a and 106b of the through-hole 106. The conductive layer 130 is disposed in the through-hole 106 and covers the isolation layer 110, and the conductive layer 130 includes a first portion 130a and a second portion 130b, wherein the first portion 130a fills a portion of the through-hole 106, and the second portion 130b is located on the sidewalls 106a and 106b in the other portion of the through-hole 106, such that the conductive layer 130 has a concave part 104. The dielectric layer 140 is disposed in the concave part 104 and fills the concave part 104. Optionally, the through silicon via structure may further include the seed layer 120. The seed layer 120 is disposed between the isolation layer 110 and the conductive layer 130. Furthermore, the material, size, configuration and effect of each component in the through silicon via structure are already described thoroughly in above embodiments and therefore are not described again.

Based on above embodiments, the dielectric layer 140 is disposed in the concave part 104 of the conductive layer 130 and fills the concave part 104, thereby the stress generated between the through silicon via structure and the substrate 100 would be reduced. Adverse effects on the devices around the through silicon via caused by the stress may further be prevented, thus the efficiency of the devices would be efficiently elevated.

FIGS. 1F-1I are cross-sectional views illustrating a manufacturing process for fabricating a conductive structure in application of the through silicon via structure according to an embodiment of the invention. In this embodiment, a conductive structure is manufactured by several processes described below. It should be notice that these processes are conducted after the removal of the dielectric layer 140, the conductive layer 130, the seed layer 120 and the isolation layer 110 located outside the opening 102 described in FIG. 1D is completed.

Referring to FIG. 1F, a block layer 150 can be formed on the through silicon via structure of the invention. The material of the block layer 150 is, for example, SiC, SiN or a composite layer composed of both SiC and SiN, and the forming method of the block layer 150 is, for example, CVD, but is not limited thereto. The block layer 150 can barrier the copper out-diffusion in the through silicon via structure.

Next, a dielectric layer 160 is further deposited on the block layer 150. The material of the dielectric layer 160 is, for example, silicon oxide, and the forming method of the dielectric layer 160 is, for example, PECVD, but the invention is not limited thereto. Then, by a metal photo etching process (for example, plasma etching), openings 152 which expose the conductive layer 130 are formed.

Then, referring to FIG. 1G, a second metal photo etching process is conducted to form a plurality of trenches 154. The second metal photo etching process can be the same as described above, but not limited thereto. In addition, the pattern of the trenches 154 can be freely designed upon requirement by people skilled in the art.

Afterwards, referring to FIG. 1H, a metal line layer 170 is formed in the dielectric layer 160. The metal line layer 170 comprises conductive parts 170a, 170b which may conduct to the conductive layer 130, and conductive parts 170c, 170d which may conduct to other portions of the conductive structure. The material of the metal line layer 170 is, for example, Cu or polysilicon. While using Cu as the material of the metal line layer 170, electroplating techniques may be used to form the metal line layer 170; while using polysilicon as the material of the metal line layer 170, for example, the metal line layer 170 may be formed by CVD.

Next, referring to FIG. 1I, a CMP process is conducted on the metal line layer 170 and the dielectric layer 160 to remove a portion of the metal line layer 170 and the dielectric layer 160 until the conductive layer 130 is exposed, by which the conductive structure using the through silicon via structure of the invention is completed.

Based on above, the through silicon via structure of the invention may be applied in integrated circuit devices in practice, thereby providing vertically conducting paths in 3D chip stacking structures.

In summary, abovementioned embodiments at least have the following advantages:

1. Devices around the through silicon via structure described in above embodiments would have better efficiency.

2. The method for fabricating the through silicon via structure described in above embodiments could be easily incorporated into current manufacturing processes, and the fabricating cost of the through silicon via structure would be lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A through silicon via structure, comprising:
a substrate having a through-hole therein;
an isolation layer disposed on two sidewalls of the through-hole;
a conductive layer disposed in the through-hole and covering the isolation layer, and the conductive layer comprises a first portion and a second portion, wherein the first portion fills a portion of the through-hole, and the second portion is located on the sidewalls in the other portion of the through-hole, such that the conductive layer has a concave part; and
a dielectric layer disposed in the concave part and filling the concave part.

2. The through silicon via structure according to claim 1, further comprising a seed layer disposed between the isolation layer and the conductive layer.

3. The through silicon via structure according to claim 1, wherein a height of the first portion is 15% to 50% of a depth of the through-hole.

4. The through silicon via structure according to claim 1, wherein a thickness of the second portion located on each of the sidewalls is 5% to 10% of a width of the through-hole.

5. The through silicon via structure according to claim 1, wherein a depth of the through-hole is 10 to 100 μm.

6. The through silicon via structure according to claim 1, wherein a width of the through-hole is 5 to 50 μm.

7. The through silicon via structure according to claim 1, wherein a height of the first portion is 5 to 25 μm.

8. The through silicon via structure according to claim 1, wherein a thickness of the second portion located on each of the sidewalls is 1 to 2 μm.

9. The through silicon via structure according to claim 1, wherein a material of the conductive layer comprises copper, poly silicon or tungsten.

10. The through silicon via structure according to claim 1, wherein a material of the dielectric layer comprises a porous dielectric material.

11. The through silicon via structure according to claim 10, wherein a material of the porous dielectric material comprises polymer and porous silicon dioxide.

12. A method for fabricating a through silicon via structure, comprising:
providing a substrate comprising a first surface and a second surface, and the first surface of the substrate has an opening formed therein;
forming an isolation layer on the substrate conformally;
forming a conductive layer on the isolation layer, wherein the conductive layer located in the opening has a concave part;
forming a dielectric layer filling the concave part;
removing the dielectric layer, the conductive layer and the isolation layer located outside the opening; and
removing a portion of the substrate and a portion of the isolation layer from the second surface of the substrate until the conductive layer is exposed, such that the opening becomes a through-hole, and the conductive layer located in the through-hole comprises a first portion and a second portion, wherein the first portion fills a portion of the through-hole, and the second portion is located on two sidewalls of the other portion of the through-hole.

13. The method according to claim 12, further comprising forming a seed layer on the isolation layer conformally before forming the conductive layer.

14. The method according to claim 12, wherein a method for removing the dielectric layer, the conductive layer and the isolation layer located outside the opening comprises chemical mechanical polishing.

15. The method according to claim 12, wherein a method for removing a portion of the substrate and a portion of the isolation layer from the second surface of the substrate comprises chemical mechanical polishing.

16. The method according to claim 12, wherein a height of the first portion is 15% to 50% of a depth of the through-hole.

17. The method according to claim 12, a thickness of the second portion located on each of the sidewalls is 5% to 10% of a width of the through-hole.

18. The method according to claim 12, wherein a material of the conductive layer comprises copper, poly silicon or tungsten.

19. The method according to claim 12, wherein a material of the dielectric layer comprises a porous dielectric material.

20. The method according to claim 19, wherein a material of the porous dielectric material comprises polymer and porous silicon dioxide.
